(19) United States
(12) Patent Application Publication
(10) Pub. No.: US 2007/0007974 A1
(43) Pub. Date: Jan. 11, 2007

(54) Method for reducing integral stress of a vertical probe with specific structure

(76) Inventors: Jinn-Tong Chiu, Dong-Shan (TW); Chi-liu Shen, Xin Dian (TW); Dar-Yuan Chang, Xin-Dian (TW)

Correspondence Address: G. LINK CO. LTD., 3550 Bell Road, Minooka, IL, 60447, US

(21) Appl. No.: 11/174,387

(22) Filed: Jul. 5, 2005

(51) Int. Cl. G01R 31/02

(52) U.S. Cl. 324/754

(57) ABSTRACT

A method for reducing integral stress of a vertical probe with specific structure is disclosed. The vertical probe includes a probe tip, an insert part and a bent part. The bent part has a first circular arc and a second circular arc and the second circular arc is provided with a radius much greater than that of the first circular arc and the second circular arc is farther away from the probe tip and smoothly extends from the first circular arc. The integral stress of the probe during probing is effectively reduced to avoid overstress.

### BACKGROUND OF THE INVENTION

1. Field of the Invention

The present invention is related to a method for reducing integral stress of a vertical probe with specific structure, in which a plurality of circular arcs in different radii are provided to reduce integral stress thereof so as to avoid the vertical probe being overstressed while in operation.

2. Brief Description of Related Art

The traditional probe card can be structurally classified into two types, cantilever type and vertical type. In case of probing smaller and higher pin count chips (high probe count), it is necessary to use the vertical type probe card to obtain desirable detection result.

The conventional vertical probe card as shown in FIG. 1 includes probes 100, an upper cover plate 110, a spacer 120, a lower cover plate 130, a substrate 200, a printed circuit board 400 and a stiffener 500. The fabricating process of the vertical probe card is described hereinafter. The straight probes 100 are individually stamped to form a bend for offering certain elasticity. Then, the probes 100 are inserted into the upper and lower cover plates 110, 130 vertically. The spacer 120 between the upper and lower cover plates 110, and 130 offers an extension space for the probes 100. This is so called “insert operation”. Hence, a probe assembly, which includes probes 100, the upper cover plate 110, the spacer 120 and the lower cover plate 130, can be complete. On the other hand, the substrate 200 is joined to the printed circuit board 400 by way of reflow soldering 300 during probe insert. Further, the probe assembly is placed on a facial side of the substrate, which is opposite to the side with reflow soldering, and the lower end of each probe 100 contacts corresponding positions of the substrate directly. Finally, the probe assembly is mounted to the stiffener 500 to complete the vertical probe card. Once the vertical probe card is in operation, the probes 100 contact the surface of the welding pad to transmit signal to the printed circuit board 400 during the probing process.

Referring to FIG. 2, each of the conventional probes 100 has a probe tip 101 for contacting with a pad on the test chip, a bent part 102 for supplying a contact force to the pad and an insert part 103 for insertion and location of the respective probe 100. During probing, inadequate contact force leads to poor electrical connection and it results in unsuccessful detection. On the other hand, excessive contact force leads to the pad being penetrated by the probe tip 101 and it results in damaged tested chip. Hence, a circular arc with a specific radius is provided to form a bent part 102 of the probe for supplying a preset contact force. However, the single circular arc offers limited benefit for the probe 100 and overstress of the probe 100 may occur for probe 100 with a diameter merely several hundred μm. Further, Taiwanese Patent Official Gazette No. 1,223,072 entitled “VERTICAL PROBE CARD” discloses a V-shaped probe 100 as shown in FIG. 3 in which a semicircular bent part 102 with a preset radius for reducing the contact force. However, overstress problem still unsolved for critical design.

### SUMMARY OF THE INVENTION

An object of the present invention is to provide a method for reducing integral stress of a vertical probe by means of specific structure design.

Another object of the present invention is to provide a vertical probe with specific structure comprises of a plurality of circular arcs in different radii to avoid overstress during operation.

In order to achieve the preceding objects, the method for reducing integral stress of a vertical probe includes following steps: (1) initializing design; (2) building a finite element model and analyzing contact force and stress by means of finite element method; (3) optimizing programming and if the result is not converged the step 4 is taken; (4) updating the probe geometry; (5) re-meshing the finite element model and restarting from step 2 again till convergence being reached; and (6) obtaining optimum probe geometry.

A vertical probe for reducing integral stress thereof according to the present invention includes a probe tip for contacting with a pad of a test chip; an insert part for locating and insertion of the probe onto a probe card; and a bent part, being disposed between the probe tip and the insert part; characterized in that the bent part has a plurality of circular arcs in different radii. The circular arcs of larger radii being disposed farther away from the probe tip and a very smooth extension is formed between any two neighboring circular arcs respectively.

### BRIEF DESCRIPTION OF THE DRAWINGS

The detail structure, the applied principle, the function and the effectiveness of the present invention can be understood with reference to the following description and accompanying drawings, in which:

FIG. 1 is a sectional view of the conventional vertical probe card;

FIG. 2 is a plan view of a conventional probe;

FIG. 3 is a plan view of another conventional probe;

FIG. 4 is a plan view of a probe with specific design parameters according to the present invention;

FIG. 4A is a sectional view along line 4A-4A shown in FIG. 4;

FIG. 4B is a sectional view along line 4B-4B shown in FIG. 4.

FIG. 5 is a flow chart of designing a probe according to the present invention;

FIG. 6 is a plan view of a probe according to the present invention;

FIG. 6A is a sectional view along line 6A-6A shown in FIG. 6; and

FIG. 6B is a sectional view along line 6B-6B shown in FIG. 6.

FIG. 7 is a plan view of a probe having a plurality of circular arcs;

FIG. 7A is a sectional view along line 7A-7A shown in FIG. 7; and

FIG. 7B is a sectional view along line 7B-7B shown in FIG. 7.

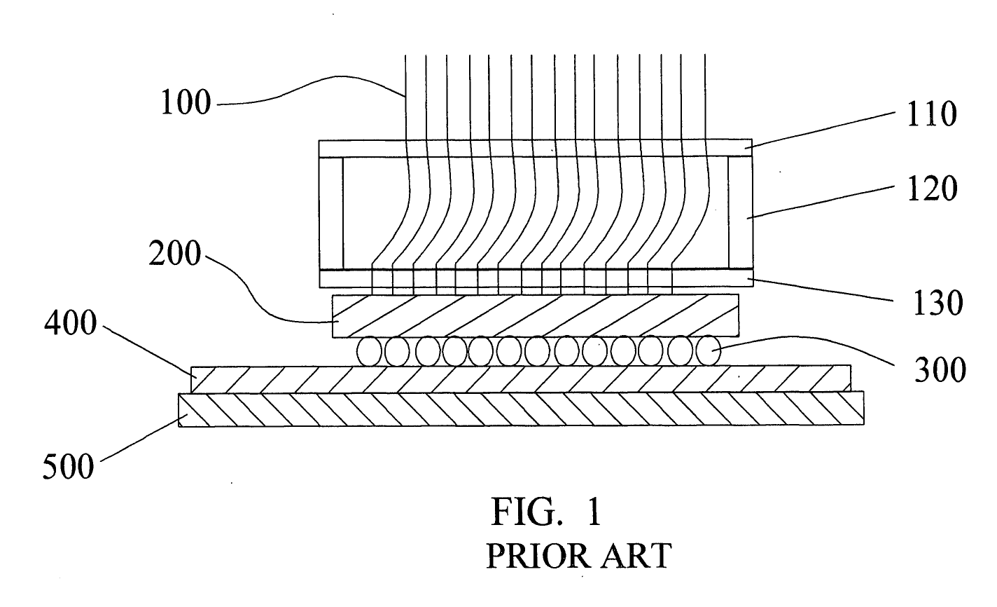

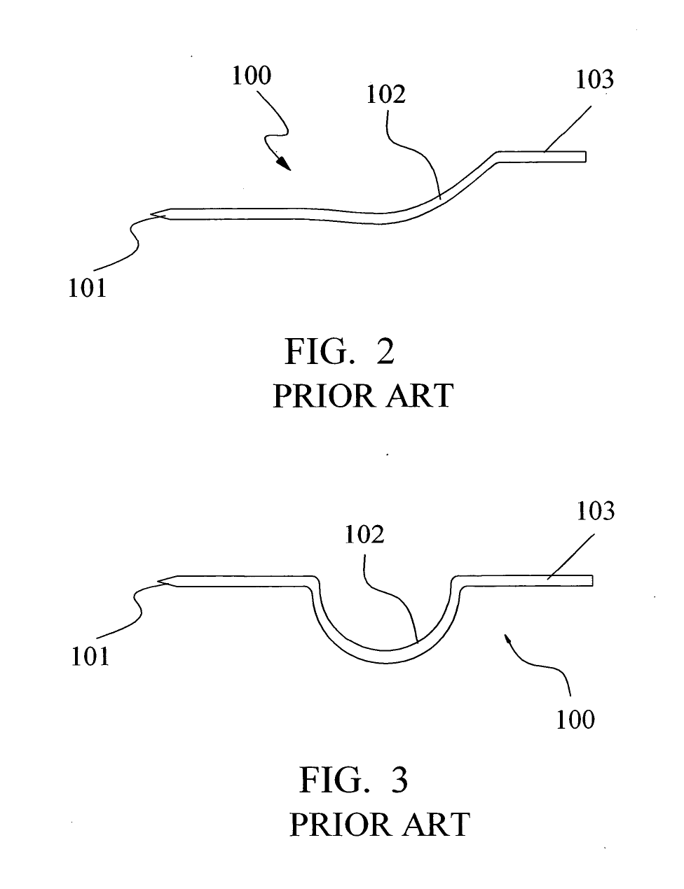

### DETAILED DESCRIPTION OF THE PRESENT INVENTION

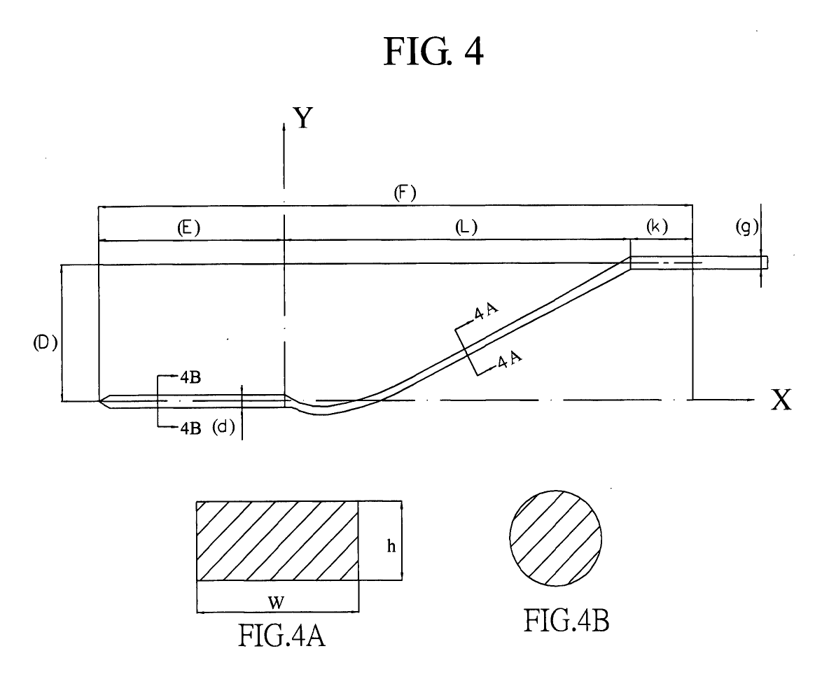

Referring to FIG. 4, the curved part of a vertical probe according to the present invention can be expressed by the following equation, which is multiple-term expression with forth power and without factor:
y(z)/D=cₜ(z/L)+c₂(z/L)²+c₃(z/L)³+(1−c₁−c₂−c₃)(z/L)⁴ (1)

Wherein, L is length of the curved part and D is the distance between two probe tips.

The preceding polynomial expression satisfies boundary conditions of displacement, i.e., y(0)=0 and y(L)=D. A finite element model can be built up based on the preceding equation and contact analysis of the vertical probe is performed with the finite element model. In case of the probe over drive being 3 mils (0.003 inch), the contact force f_{c} and the maximum Von Mises stress σₘₐₓ. The optimized model of the probe structure is capable of being expressed hereinafter.

Target function for minimizing the integral stress of the probe is:
σₘₐₓ (2)

The constraint is that the contact forces between the probe and the welding pad must be greater than designed value:
f_{c}≧f_{d} (3)

The design variable x is the coefficients of c₁, c₂ and c₃. Quadratic programming method is applied to solve the optimum problem of probe geometry parameters. Nonlinear optimized problem can be expressed in the following:
min f(x) (4)
The constraint is gⱼ(x)≧0, for j=1 . . . , m_{c} (5)
wherein, m_{c} is number of unequal expression restrictions, x is design variable set and N is number of design variables. The design variables are between an upper and lower design variables x_{λ}≦x≦x_{α}
Wherein, x_{λ} and x_{μ} are upper and lower limit.
   Solving Processes of Optimization

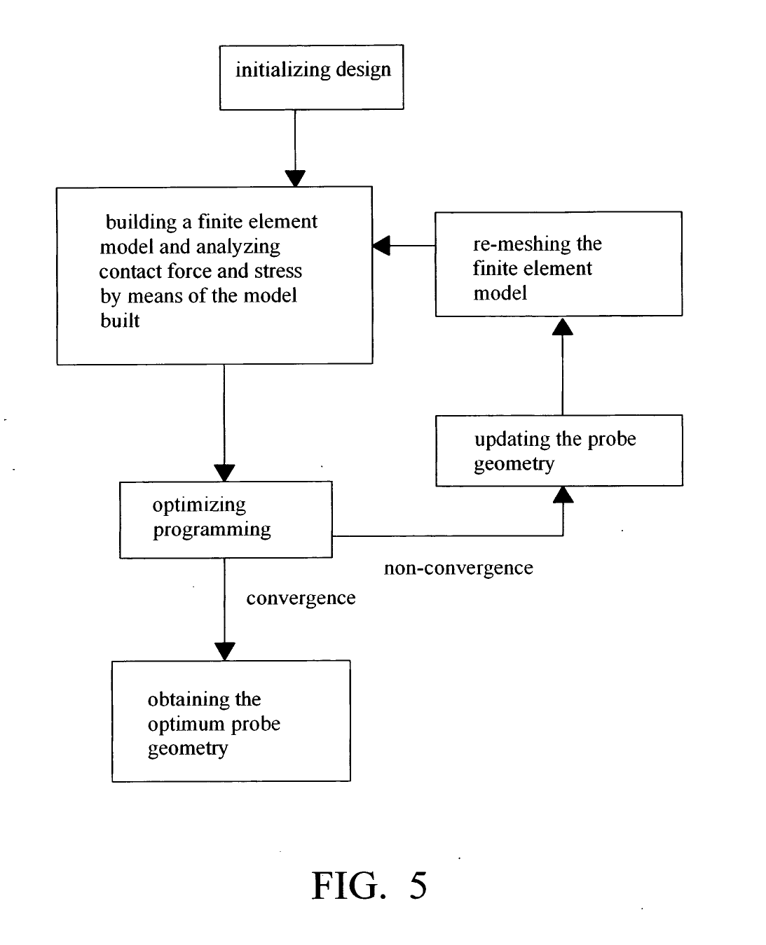

The flow chart demonstrating optimization process for solution of the present invention is shown in FIG. 5. Step 1 is to initialize design in which the design variables, the target function and restrictions are defined first. Step 2 is to build a finite element model and analyze stress by finite element method (FEM) with which contact force and maximum stress of the probe tip can be figured out. Geometric parameters of the probe are setup by processing file; Step 3 is the optimization, which are proceeded by setting up target function and constrains, and then changing design parameters until the target value converged to allowable error under the constrains. In case of no convergence being reached, step 4 is performed to update the probe geometry. Step 5 is to re-mesh the finite element model and then restart from step 2 again till convergence being reached. Finally, step 6 for optimum probe geometry is obtained.

An example with actual data is explained hereinafter. It is noted that the present invention is not limited to the example.

The dimensional data is listed in the following:
d=0.1 g=0.101
h=0.043 k=0.624
D=1.273 E=1.551
F=5.717 L=3.498

The snake belly is approximately provided with width thereof w=0.182.

The contact force is set as 11 g and the geometry is initially set as quadratic curve. However the geometry is a multiple-term expression during the optimization process. It can be two approximate circular curves with different radii. Under a preset value of design contact force, fatigue strength of the probe can increase effectively and the maximum Von Mises stress being decreased by 24%. When OD=75 μm, results before and after optimization are shown in the following table.

| | | | | Maximum | Contact |
|---|---|---|---|---|---|
| | | | | Von Mises | force |
| | c1 | c2 | c3 | stress | with pad |
| Before | 0 | 1 | 0 | 702 Mpa | 16.85 g |
| optimization | | | | | |
| After | −0.3505 | 0.8546 | 1.3102 | 533 Mpa | 11 g |
| optimization | | | | | |

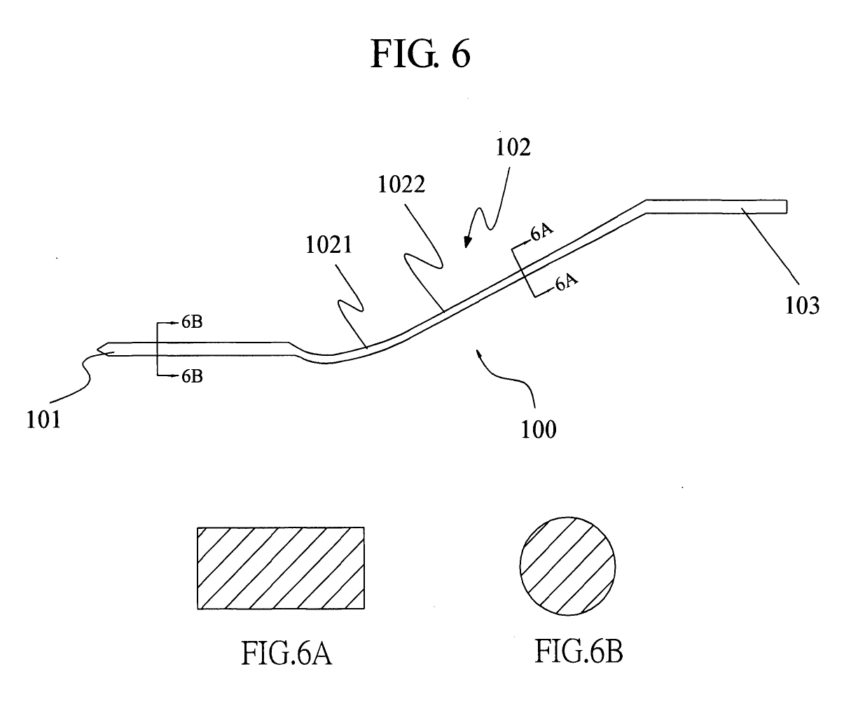

Referring to FIG. 6, in which the preceding optimized results of the probe is illustrated. In order to explain simply, the designated reference numbers of the present invention are the same as the prior art device for identical parts. The probe 100 of the present invention includes a probe tip 101 with a circular cross section, an insert part 103 for insertion and locating of probe to a probe card and a bent part 102 with a rectangular cross section between the tip 101 and the insert part 103 for providing a contact force between the probe 100 and the pad. When probing, the rectangular cross section of probe 100 allows controllable bent direction and curvature. Wherein, the bent part 102 has a first circular arc 1021 and a second circular arc 1022 and the second circular arc 1022 is provided with a radius much greater than that of the first circular arc. The second circular arc 1022 is far away the probe tip 101 and very smoothly extends from the first circular arc 1021.

When probing, the probe tip 101 contacts with the pad and the first and second circular arcs 1021, 1022 supply a designed contact force to allow proper electric connection between the probe 100 and the pad. Besides, the integral stress of the probe decreases tremendously as shown in the preceding comparison table due to the first and second circular arcs 1021, 1022. This effectively avoids overstress of the probe 100 when compared with traditional probe. The two circular arcs arranged on the bent part 102 with different radii is only an example. The radii of the circular arc, which is farther away from the probe tip 101, is greater. Different circular arcs are connected smoothly. Alternatively, more than two circular arcs can be arranged,

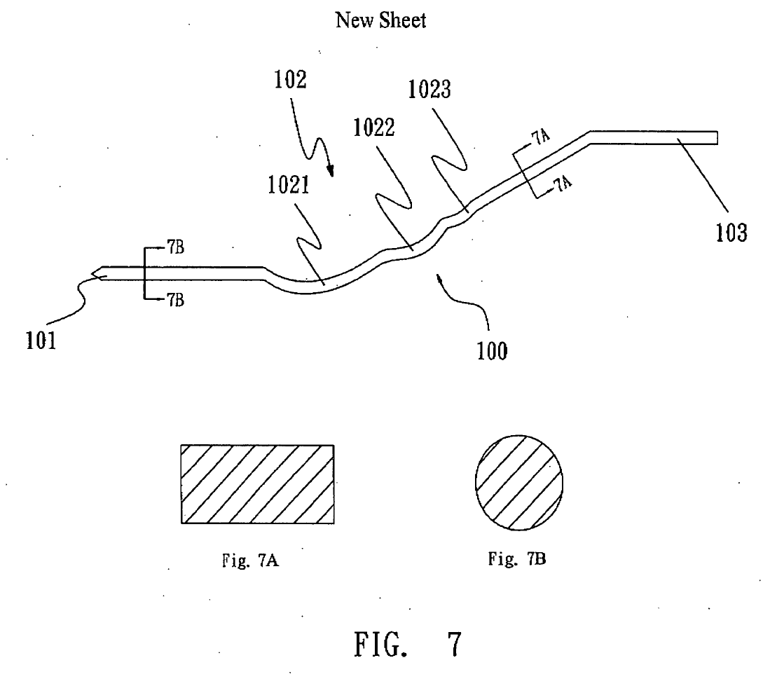

Referring to FIGS. 7, 7A and 7B, the probe 100 includes a probe tip 101 with a circular cross section, an insert part 103 for insertion and locating of probe to a probe card and a bent part 102 with a rectangular cross section between the tip 101 and the insert part 103 for providing a contact force between the probe 100 and the pad. Wherein, the bent part 102 has a plurality of circular arcs 1021, 1022, 1023 . . . . The circular arcs with larger radii are disposed farther away from the probe tip 101 and a smooth extension is formed between any two neighboring circular arcs.

It is appreciated that the method for decreasing integral stress of the vertical probe with specific structure according to the present invention provides a plurality of stamped circular arcs to supply proper contact force during probing so that the electric connect between the probe and the pad is adequate.

While the invention has been described with referencing to a preferred embodiment thereof, it is to be understood that modifications or variations may be easily made without departing from the spirit of this invention, which is defined by the appended claims.

1-4. (canceled)

5-10. (canceled)

11. A vertical probe for reducing integral stress, comprising;
a probe tip with a circular cross section for contacting with a welding pad of a test chip;
an insert part for insertion and location of the probe on a probe card; and
a bent part with a rectangular cross section, being disposed between the probe tip and the insert part;
wherein, the bent part has a first circular arc and a second circular arc and the second circular arc is provided with a radius much greater than that of the first circular arc and the second circular arc is farther away from the probe tip and smoothly extends from the first circular arc, and said first and second circular arcs are bent in the same direction.

12. A vertical probe for reducing integral stress thereof, comprising;
a probe tip with a circular cross section for contacting with a welding pad of a test chip;
an insert part for insertion and location of the probe on a probe card; and
a bent part with a rectangular cross section, being disposed between the probe tip and the insert part;
wherein, the bent part has a plurality of circular arcs in different radii, the circular arcs with larger radii are disposed farther away from the probe tip and a smooth extension is formed between any two neighboring circular arcs, and said circular arcs are bent in the same direction.
